(19) United States
(12) Patent Application Publication
(10) Pub. No.: US 2024/0027916 A1
(43) Pub. Date: Jan. 25, 2024

(54) FINGERPRINTING AND PROCESS CONTROL OF PHOTOSENSITIVE FILM DEPOSITION CHAMBER

(71) Applicant: Applied Materials, Inc., Santa Clara, CA (US)

(72) Inventors: RUIYING HAO, San Jose, CA (US); TODD EGAN, Fremont, CA (US); EDWARD BUDIARTO, Fremont, CA (US); PAOLA DE CECCO, Salinas, CA (US); REGINA FREED, Los Altos, CA (US); BEKELE WORKU, San Jose, CA (US); MADHUR SACHAN, Belmont, CA (US); LUISA BOZANO, Los Altos Hills, CA (US); KELVIN CHAN, San Ramon, CA (US)

(21) Appl. No.: 18/198,073

(22) Filed: May 16, 2023

Related U.S. Application Data
(60) Provisional application No. 63/391,064, filed on Jul. 21, 2022.

(51) Int. Cl. G03F 7/20; G03F 7/00

(52) U.S. Cl. CPC G03F 7/70491; G03F 7/70653; G03F 7/706843; G03F 7/70808; G03F 7/7085

(57) ABSTRACT

Embodiments disclosed herein include a method of monitoring a photoresist deposition process. In an embodiment, the method comprises depositing a photoresist layer to a first thickness over a substrate, measuring a property of the photoresist layer with a first electromagnetic (EM) radiation source, depositing the photoresist layer to a second thickness over the substrate, and measuring the property of the photoresist layer with the first EM radiation source.

### CROSS-REFERENCE TO RELATED APPLICATIONS

This application claims the benefit of U.S. Provisional Application No. 63/391,064, filed on Jul. 21, 2022, the entire contents of which are hereby incorporated by reference herein.

### BACKGROUND

### 1) Field

Embodiments of the present disclosure pertain to the field of semiconductor processing and, in particular, to process control of methods for depositing photosensitive film without inducing a chemical change in the film.

### 2) Description of Related Art

Lithography has been used in the semiconductor industry for decades for creating 2D and 3D patterns in microelectronic devices. The lithography process involves spin-on deposition of a film (photoresist), irradiation of the film with a selected pattern by an energy source (exposure), and removal (etch) of exposed (positive tone) or non-exposed (negative tone) region of the film by dissolving in a solvent. A bake will be carried out to drive off remaining solvent.

The photoresist should be a radiation sensitive material and upon irradiation a chemical transformation occurs in the exposed part of the film which enables a change in solubility between exposed and non-exposed regions. Using this solubility change, either exposed or non-exposed regions of the photoresist is removed (etched). The photoresist is then developed and the pattern can be transferred to the underlying thin film or substrate by etching. After the pattern is transferred, the residual photoresist is removed and repeating this process many times can give 2D and 3D structures to be used in microelectronic devices.

Several properties are important in lithography processes. Such important properties include sensitivity, resolution, lower line-edge roughness (LER), etch resistance, and ability to form thinner layers. When the sensitivity is higher, the energy required to change the solubility of the as-deposited film is lower. This enables higher efficiency in the lithographic process. Resolution and LER determine how narrow features can be achieved by the lithographic process. Higher etch resistant materials are required for pattern transferring to form deep structures. Higher etch resistant materials also enable thinner films. Thinner films increase the efficiency of the lithographic process.

### SUMMARY

Embodiments disclosed herein include a method of monitoring a photoresist deposition process. In an embodiment, the method comprises depositing a photoresist layer to a first thickness over a substrate, measuring a property of the photoresist layer with a first electromagnetic (EM) radiation source, depositing the photoresist layer to a second thickness over the substrate, and measuring the property of the photoresist layer with the first EM radiation source.

In an embodiment, a semiconductor processing tool is described. In an embodiment, the semiconductor processing tool comprises a chamber, a susceptor configured to support a substrate, a gas inlet for flowing one or more processing gasses into the chamber, a window, and an optical inspection tool for measuring one or more film properties of a photoresist layer on the substrate through the window, where the optical inspection tool is configured to provide a short burst of electromagnetic (EM) radiation that allows for measuring the one or more film properties of the photoresist layer without inducing a chemical change in the photoresist layer.

Embodiments may also comprise a semiconductor processing tool that includes a chamber, a susceptor for supporting a substrate in the chamber, a window along a wall of the chamber, where the window allows for electromagnetic (EM) radiation to pass through the chamber, an inspection tool for measuring one or more film properties of a photoresist layer on the substrate through the window, where the inspection tool is configured to provide a short burst of EM radiation that allows for measuring the one or more film properties of the photoresist layer without inducing a chemical change in the photoresist layer, where the short burst has a duration of approximately 100 milliseconds or less, and where a wavelength of the EM radiation is approximately 400 nm or less.

### BRIEF DESCRIPTION OF THE DRAWINGS

FIG. 1 is a cross-sectional illustration of a semiconductor processing tool for depositing a photoresist layer with a dry deposition process, in accordance with an embodiment.

FIG. 2A is a cross-sectional illustration of a substrate with a photoresist layer deposited to a first thickness, in accordance with an embodiment.

FIG. 2B is a cross-sectional illustration of a substrate with a photoresist layer deposited to a second thickness, in accordance with an embodiment.

FIG. 3 is a cross-sectional illustration of a semiconductor processing tool for depositing a photoresist layer with a dry deposition process that includes a feedback loop, in accordance with an embodiment.

FIG. 4 is a process flow diagram of a process for depositing a photoresist layer with an on-board metrology (OBM) unit for providing in-situ feedback control, in accordance with an embodiment.

FIG. 5 is an illustration of a block diagram of an exemplary computer system, in accordance with an embodiment of the present disclosure.

### DETAILED DESCRIPTION

Methods of process control for depositing photosensitive film without inducing a chemical change in the film is described herein. In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

To provide context, photoresist systems used in extreme ultraviolet (EUV) lithography suffer from low efficiency. That is, existing photoresist material systems for EUV lithography require high dosages in order to provide the needed solubility switch that allows for developing the photoresist material. Traditionally, carbon based films called organic chemically amplified photoresists (CAR) have been used as a photoresist. However, more recently organic-inorganic hybrid materials (metal-oxo) have been used as a photoresist with extreme ultraviolet (EUV) radiation. Such materials typically include a metal (such as Sn, Hf, Zr), oxygen, and carbon. Transformation from deep UV (DUV) to EUV in the lithographic industry facilitated narrow features with high aspect ratio. Metal-oxo based organic-inorganic hybrid materials have been shown to exhibit lower line edge roughness (LER) and higher resolution which are required for forming narrow features. Also, such films have higher sensitivity and etch resistance properties and can be implemented to fabricate relatively thinner films.

Currently, a metal-oxo photoresist is deposited by spin-on methods which includes wet chemistries. Post bake processes are required to drive off any remaining solvents from the film and to render the film stable. Also, wet methods can generate a lot of wet waste that the industry wants to move away from. Photoresist films deposited by spin-on methods often result in non-uniformity issues. In accordance with embodiments of the present disclosure, addressing one or more of the above issues, processes for vacuum deposition of a metal-oxo photoresist with a feedback control loop are described herein.

In accordance with one or more embodiments of the present disclosure, dry deposition and oxidation treatment approaches for forming positive tone photoresist films are described herein. In some embodiments, thermal chemical vapor deposition (CVD) is used for dry deposition of a positive tone photoresist film. In other embodiments, plasma enhanced chemical vapor deposition (PECVD) is used for dry deposition of a positive tone photoresist film. In an embodiment, the dry deposition process is not a condensation process. In another embodiment, the dry deposition process is a condensation process. In one such condensation process embodiment, a wafer/substrate is maintained at a temperature at which the metal precursor can be condensed. Precursor condensation can be achieved by maintaining the wafer temperature at a lower temperature than a precursor ampoule temperature.

However, dry deposition processes are not without issue. For example, control of the flow of processing gasses into the chamber can be a difficult parameter to control to the specifications necessary to produce high quality photoresist films. Accordingly, embodiments disclosed herein include semiconductor processing tools that include an on-board metrology (OBM) system. The OBM system allows for in-situ monitoring of one or more properties of the photoresist layer in order to provide feedback control to a controller that implements the deposition process. The OBM system allows for changes to processing gas flow rates, pressures, temperatures, and the like in order to provide improved film properties (e.g., thickness uniformity, composition uniformity, LER, etch resistance, etc.). The OBM system also allows for process fingerprinting, chamber matching, and the like.

In a particular embodiment, the OBM system includes an optical metrology tool, such as, but not limited to, an ellipsometry tool, a reflectometry tool, or a tool for implementing fluorescence of photoelectron emittance. The use of such OBM systems is not without issue. Particularly, the electromagnetic (EM) radiation emitted by the system desirably does not cause a chemical reaction within the photoresist layer, or at least produces a negligible change to the chemistry of the photoresist layer. Accordingly, embodiments disclosed herein include OBM systems that emit light at a short duration (e.g., 100 milliseconds or less). The spot size of the EM radiation may also be increased in order to reduce the power density of the EM radiation on the photoresist layer. For example, a spot size of 1 mm² may be used compared to a 50 μm² spot size.

In a particular embodiment, the photoresist layer is a metal oxo photoresist film, such as a tin-oxide photoresist layer. The photoresist layer may be deposited with a dry deposition process. However, it is to be appreciated that OBM systems for monitoring photoresist properties can be used with any photoresist material system (e.g., CARs) and for photoresist materials deposited with any deposition process.

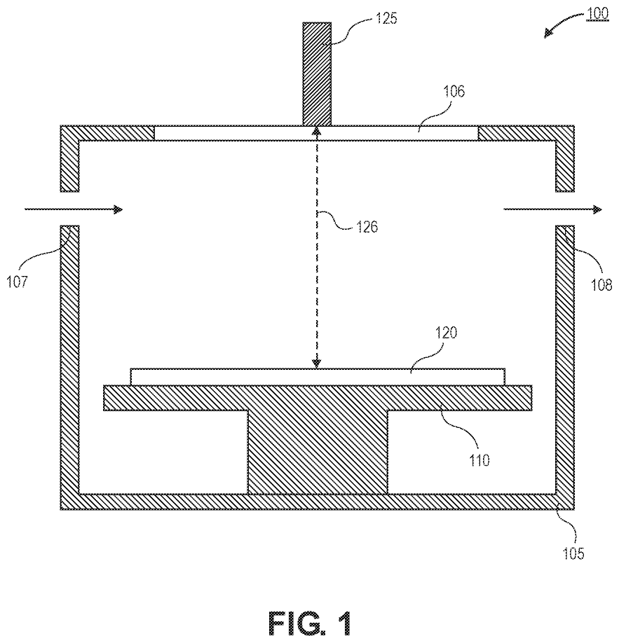

Referring now to FIG. 1, a cross-sectional illustration of a semiconductor processing tool 100 is shown, in accordance with an embodiment. In an embodiment, the semiconductor processing tool 100 may comprise a chamber 105. The chamber 105 may be suitable for maintaining a sub-atmospheric pressure within the chamber 105 (e.g., a vacuum pressure). In an embodiment, the chamber 105 may have an inlet 107 and an outlet 108. The inlet 107 may be configured to flow one or more processing gasses into the interior of the chamber 105. While a single inlet 107 is shown, it is to be appreciated that any number of inlets 107 (e.g., one for each processing gas) may be used in some embodiments. For example, when two processing gasses need to be kept separate from each other until reaching the chamber 105, a pair of inlets 107 may be used. While shown as flowing into the chamber 105 through a sidewall, in other embodiments, one or more of the processing gasses may be flown into the chamber through the lid with a showerhead type inlet 107. In an embodiment, an outlet 108 may be used to vent unreacted process gas, byproducts, and the like from the chamber 105. The outlet 108 may be coupled to vacuum source, such as a vacuum pump, a throttle valve, and the like.

In an embodiment, the chamber 105 may contain a susceptor 110 or the like. The susceptor 110 may be suitable for securing a substrate 120 onto which the photoresist layer is deposited. The susceptor 110 may include any chucking architecture, such as an electrostatic chuck (ESC) in order to secure the substrate 120 to the susceptor 110. The susceptor 110 may be configured to rotate in some embodiments, in order to provide a more uniform process result. The susceptor 110 may also include utilities (e.g., heating, cooling, etc.) in order to control a temperature of the substrate 120.

It is to be appreciated that one or more process parameters of the semiconductor processing tool 100 may be controlled in order to provide improved process uniformity outcomes. For example, gas flow rates into the outlet 107 may be controlled, a temperature of the substrate 120 may be controlled, a rotation speed of the substrate 120 may be controlled, a pressure within the chamber 105 may be controlled, among many other process parameters.

In an embodiment, the semiconductor processing tool 100 may also comprise an OBM system 125. The OBM system 125 may be an optical metrology tool in some embodiments. For example, the OBM system 125 may include an ellipsometer, a reflectometer, or functionality for determining fluorescence of photoelectron emittance. The OBM 125 may emit EM radiation 126 that is directed to the substrate 120. The EM radiation passes through a window 106 in the chamber 105. The window 105 is shown over the lid of the chamber 105, but the window 106 (and the OBM system 125) may be provided over any of the surfaces of the chamber 105. As indicated by the double sided arrow, the EM radiation 126 reflects back to the OBM system 125 in order to measure photoresist layer conditions. For example, the OBM system 125 may be used to determine a thickness, a surface roughness, a chemical composition, a complex dielectric constant, or a complex refractive index of the photoresist layer.

Since the OBM system 125 is integrated with the semiconductor processing tool 100, real time analysis of the photoresist film can be provided in order to allow for feedback control of the deposition process. For example, as will be described in greater detail below, a controller or the like may receive conditions of the photoresist layer as a feedback input, and the controller may output control signals to change one or more processing conditions.

While shown as being integrated with the deposition process chamber 105 as an in-situ device, it is to be appreciated that the OBM system 125 may also be an ex-situ device. For example, the OBM system 125 may be provided on the semiconductor processing tool, but at a different station than the deposition process chamber 105. In such embodiments, photoresist film properties are measured post deposition. However, the information provided post deposition may still be used to monitor, control, and/or tune subsequent iterations of the deposition process.

As noted above, the use of an OBM system 125 needs to be carefully implemented in order to prevent chemical reactions within the photoresist layer. That is, using standard optical metrology systems, the EM radiation has a power, duration, spot size, etc. that may result in the premature chemical reaction in the photoresist layer. This may result in exposure defects, such as an overexposure, exposure of the wrong area, or the like. For example, photoresist may be extremely sensitive to wavelengths under 400 nm, such as the wavelengths in a UV, DUV, or EUV tools. On the other hand, photoresist may be less sensitive to wavelengths over 400 nm. However, the larger wavelength impacts the ability to resolve the optical or material properties of the material, hence providing limited insight into the optical or material properties of interest for predicting the behavior of the photoresist film. Accordingly, embodiments disclosed herein include OBM systems 125 that generate useful feedback using EM radiation at or below 400 nm without exposing the photoresist layer to a level of EM radiation that results in a chemical change of the photoresist layer.

In an embodiment, the dose of EM radiation supplied by the OBM system 125 is carefully controlled. As used herein, a dose of EM radiation may refer to its size (e.g., frequency or wavelength) and its longevity. The first EM source is used to expose an unpatterned photoresist to a single short pulse of EM radiation and acquire the reflected light in order to measure optical or material properties of the photoresist, such as the film thickness, without substantially changing the optical or material properties of the photoresist. The single shot pulse duration, intensity and spectral composition can be tuned to achieve the best performance based on material characteristics. The photoresist is not changed by exposure to the single short pulse because the dose of EM radiation is too small to alter the chemical and morphological properties of the photoresist. The EM radiation may be any suitable form of EM radiation such as ultraviolet (UV) light, X-rays, Extreme UV (EUV) light, or other suitable forms of EM radiation. In some embodiments, electron beams may also be suitably used in place of or in conjunction with the EM radiation.

Changes in the optical or material properties of the photoresist can inform adjustments in deposition parameters, and/or subsequent process steps, such as exposure dosage, with the goal of improving the lithographic print quality. Exemplary improvements of the lithographic print quality can include critical dimensions (CDs), CD uniformity, line edge roughness (LER), line width roughness (LWR)), dose to size, or any combination thereof. For example, a process gas flow rate over a substrate during a photoresist deposition process or an exposure dose or longevity may be increased or decreased to account for the real-time measurements of an optical property of a photoresist on the substrate. Gas flow rates, deposition duration, and deposition temperatures may also be tuned or adjusted based on the photoresist properties measured by the OBM system 125.

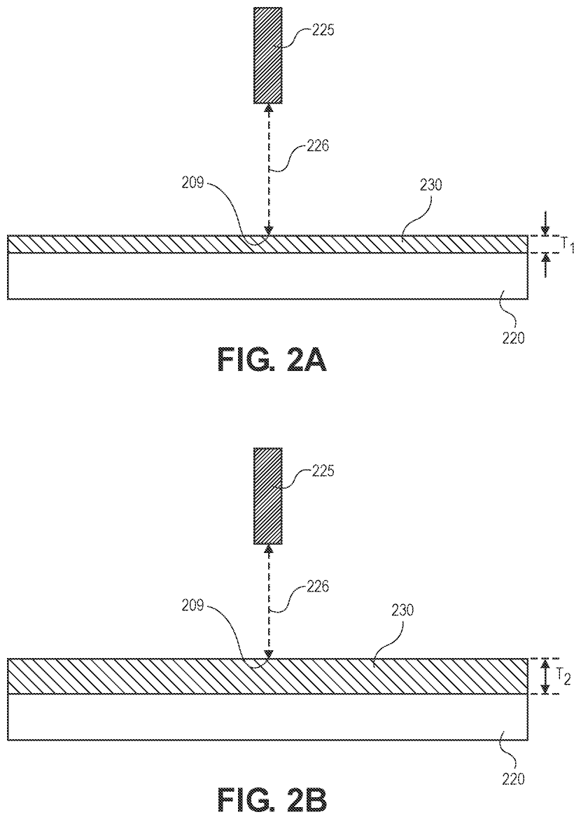

Referring now to FIG. 2A, a cross-sectional illustration of a substrate 220 that is being processed (e.g., in a semiconductor processing tool 100) is shown, in accordance with an embodiment. In an embodiment, the structure of the semiconductor processing tool 100 other than the OBM system 225 is omitted for clarity. As shown, a photoresist layer 230 may be deposited onto a surface of the substrate 220. The unpatterned photoresist layer 230 may be formed of any suitable photoresist material. The photoresist material can be or include one or more CARs, one or more photoabsorption resists, one or more metallic materials, one or more metal oxide (MOX) materials, one or more non-metallic materials, or any combination thereof. In some examples, the photoresist 230 contains photoresist materials which can be or include metals, metal oxides, and/or clusters of one or more elements including indium, tin, bismuth, antimony, cesium, molybdenum, hafnium, zirconium iron, cobalt, nickel, copper, zinc, silver, platinum, lead, iodine, tellurium, or any combination thereof. In some embodiments, the photoresist 230 is a dry photoresist. The photoresist may include a positive or negative tone resist resin layer which may include, but is not limited to, acrylates, Novolac resins, poly(methylmethacrylates), and poly(olefin sulfones). The photoresist may also include a photoacid generator which may include, but is not limited to sulfonate compounds, onium salts, introbenzyl esters, striazine derivatives, ionic iodonium sulfonates, perfluoroalkanesulfonates, aryl triflates and derivatives and analogs thereof, pyrogallol derivatives, and alkyl disulfones. In one or more examples, upon exposure to EM radiation, the photoacid generator produces or generates one or more charged species which result in latent acid images in the resist resin. In some embodiments, a photomask or reticle may be configured to transfer a pattern containing lines to the photoresist. In other embodiments, a maskless lithography technique may be used.

The photoresist layer 230 may be analyzed with the OBM system 225. For example, an exposure to EM radiation 226 may be provided to the photoresist layer 230 and reflected back to the OBM system 225. The OBM system 225 may be used to determine a thickness T₁ of the photoresist layer 230. Though, it is to be appreciated that other material and/or optical properties, such as those described in greater detail above, may also be measured by the OBM system 225.

In an embodiment, the OBM system 225 exposes the unpatterned photoresist layer 230 to a first dose of EM radiation at a first location 209 on the unpatterned photoresist layer 230 in order to measure an optical or material property of the photoresist layer 230. The optical or material property may include the photoresist thickness T₁, surface roughness, chemical composition, complex dielectric constant, complex refractive index, or other optical property of the photoresist layer 230 and may be determined with ellipsometry, reflectometry, or the fluorescence of photoelectron emittance. The EM radiation 226 may be any suitable form of EM radiation, such as UV light, Xrays, EUV light, or other suitable forms of EM radiation. In some embodiments, electron beams may also be suitably used in place of or in conjunction with the EM radiation 226. The first dose of EM radiation 226 is a single short pulse of EM radiation which does not change the optical or material properties of the photoresist layer 230.

The first dose of EM radiation 226 may have a longevity of less than or equal to about 100 milliseconds, such as less than or equal to about 100 milliseconds, such as less than or equal to about 2 milliseconds, such as less than or equal to about 1 millisecond, such as less than or equal to about 2 microseconds, such as less than or equal to about 1 microsecond. The first dose of EM radiation 226 may have a wavelength of between about 13 nm and about 800 nm, or between about 200 nm and about 800 nm. In some embodiments, the OBM system 225 may include a scanning beam or an imager in order to obtain spatial resolution of the photoresist layer 230. For example, a scanning beam or an imager may provide information on surface morphology or defects in the photoresist layer 230.

Referring now to FIG. 2B, a cross-sectional illustration of the substrate 220 after further photoresist layer 230 deposition is shown, in accordance with an embodiment. In an embodiment, the photoresist layer 230 may have been deposited to a second thickness T₂. At the second thickness T₂ the OBM system 225 may provide a second analysis of the photoresist layer 230. In a particular embodiment, the analysis may be at the same location 209 on the substrate 220. The same location 209 may be used since the substrate 220 does not need to be displaced between readings with the OBM system 225. As such, differences in the material properties attributable to certain non-uniformities present in the photoresist layer 230 may be avoided.

In an embodiment, the second reading may use optical properties substantially similar to those used to provide the material analysis in FIG. 2A. For example, a short pulse duration with a similar or same wavelength may be used for the EM radiation 226 in FIG. 2B. As such, the photoresist layer 230 does not undergo any chemical or morphological changes as a result of the EM radiation 226.

It is to be appreciated that while two readings (e.g., FIG. 2A and FIG. 2B) are shown as an example, any number of readings of the photoresist layer 230 during its deposition may be provided. In an embodiment, the readings may be done at preset time intervals. In other embodiments, the readings may be done substantially continuously. As used herein, continuously may refer to short pulses of EM radiation that are repeated at predetermined intervals that are spaced (temporally) enough so that no chemical or morphological change occurs in the photoresist layer 230. That is to say, “continuously” does not necessarily refer to a constant exposure to EM radiation 226, which may result in a chemical or morphological change in the photoresist layer 230.

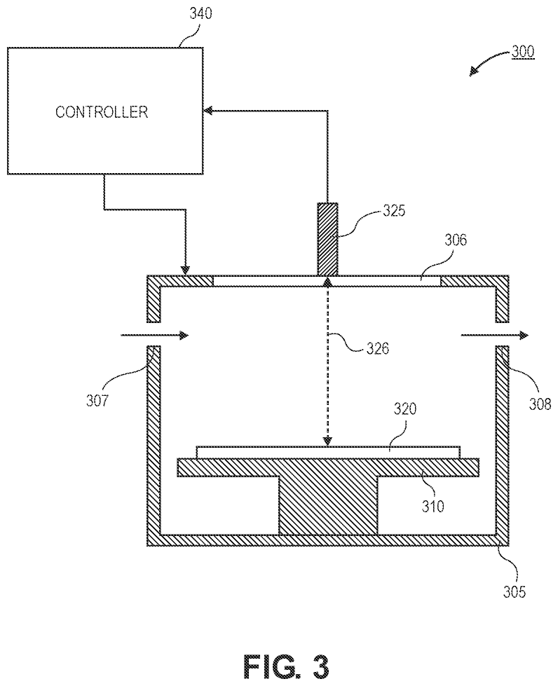

Referring now to FIG. 3, a cross-sectional illustration of a semiconductor processing tool 300 is shown, in accordance with an additional embodiment. The semiconductor processing tool 300 in FIG. 3 may be substantially similar to the semiconductor processing tool 100 in FIG. 1, with the addition of a controller 340. For example, the semiconductor processing tool 300 may comprise a chamber 305 with inlets 307, an outlet 308, a susceptor 310 for holding a substrate 320, a window 306, and an OBM system 325 for exposing the substrate 320 to EM radiation 326.

In an embodiment, the controller 340 may include a processor, a memory, and the like. The controller 340 may be configured to control a photoresist deposition process on the substrate 320 within the chamber 305. For example, the controller 340 may obtain a process recipe stored in an internal memory (or from an external memory), and control the semiconductor processing tool 300 in order to execute the process recipe. In an embodiment, the controller 340 may further be coupled to the OBM system 325. For example, readings taken by the OBM system 325 may be used as a feedback input to the controller 340. The controller 340 may then use the feedback input in order to change one or more process parameters of the process recipe in order to improve the deposition of the photoresist layer. For example, the process recipe may be changed to more closely match the thickness of the photoresist layer to a target thickness. In another example, flow rates of processing gasses may be changed in order to change a composition of the photoresist layer to more closely match a target material composition. It is to be appreciated that many different processing parameters may be changed (in isolation or as a set of multiple changes) in order to control material composition, process uniformity, and the like.

Embodiments may also allow for improved chamber matching. Chamber matching may refer to the ability to produce similar outcomes while using different chambers. Chamber matching is improved since the feedback generated by the OBM system 325 can be used to converge onto a target outcome. As such, multiple different chambers can each converge to the same target outcome using the provided feedback for each chamber. This is in contrast to existing chamber matching processes which need to find the specific chamber settings on different chambers that result in the same process outcomes. This is difficult due to inherent (and non-uniform) chamber drift of the different semiconductor processing tools.

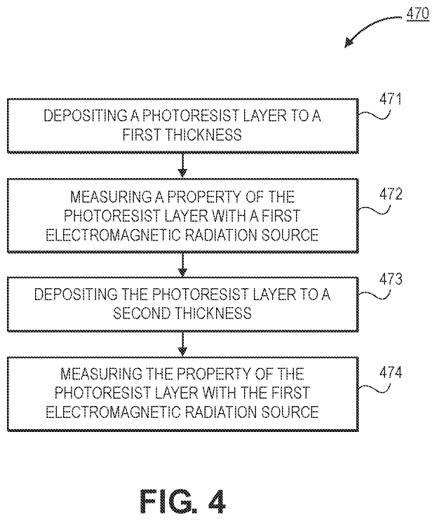

Referring now to FIG. 4, a process flow diagram of a process 470 for depositing a photoresist layer on a substrate is shown, in accordance with an embodiment. In an embodiment, the process 470 may be implemented on a semiconductor processing tool that includes an OBM system that is configured to provide feedback without changing (chemically or morphologically) the photoresist layer.

In an embodiment, process 470 may begin with operation 471, which comprises depositing a photoresist layer on a substrate to a first thickness. In an embodiment, the photoresist layer may be similar to any of the photoresist layers described in greater detail herein. For example, the photoresist layer may include a CAR, and/or a metal oxo resist. In a particular embodiment, the photoresist layer is suitable for EUV lithography. In an embodiment, the photoresist layer may be deposited with any suitable deposition process. In a particular embodiment, the deposition process is a dry deposition process, such as CVD or the like.

In an embodiment, process 470 may continue with operation 472, which comprises measuring a property of the photoresist layer with a first EM radiation source. In an embodiment, the first EM radiation source may be part of an OBM system. The OBM system may include an ellipsometer, a reflectometer, or a device for determining fluorescence of photoelectron emittance. In an embodiment, the property that is measured may include one or more of a thickness, a composition, a chemical state, an optical property, or any other property described in greater detail herein.

In an embodiment, the first EM radiation is configured to be at a dose that does not cause morphological or chemical change in the photoresist layer. For example, the pulse duration may be less than or equal to about 100 milliseconds, such as less than or equal to about 100 milliseconds, such as less than or equal to about 2 milliseconds, such as less than or equal to about 1 millisecond, such as less than or equal to about 2 microseconds, such as less than or equal to about 1 microsecond. The first EM radiation source may have a wavelength of between about 13 nm and about 800 nm. In a particular embodiment, the first EM radiation source may have a wavelength equal to or less than approximately 400 nm.

In an embodiment, the process 470 may continue with operation 473, which comprises depositing the photoresist layer to a second thickness over the substrate. In an embodiment, the deposition process may be substantially similar to the deposition process used in operation 471. For example, a dry deposition process, such as CVD or the like may be used in some embodiments.

In an embodiment, the process 470 may continue with operation 474, which comprises measuring the property of the photoresist layer with the first EM radiation source. In an embodiment, the first EM radiation source may be used to measure the property using ellipsometry, reflectometry, or fluorescence of photoelectron emittance. In an embodiment, the property may be the same property (or properties) measured during operation 472. In a particular embodiment, the first EM radiation source is used with a dose that does not change (chemically or morphologically) the photoresist layer. For example, a dose of the EM radiation source may have a longevity that is less than or equal to about 100 milliseconds, such as less than or equal to about 100 milliseconds, such as less than or equal to about 2 milliseconds, such as less than or equal to about 1 millisecond, such as less than or equal to about 2 microseconds, such as less than or equal to about 1 microsecond. The first EM radiation source may have a wavelength of between about 13 nm and about 800 nm. In a particular embodiment, the first EM radiation source may have a wavelength equal to or less than approximately 400 nm.

In some embodiments, the process 470 may also include a feedback loop. In a particular embodiment, the measured properties are sent to a controller. The controller uses the measured properties in order to change one or more processing parameters in order to converge the photoresist layer to a desired processing outcome. In an embodiment, process 470 may be repeated any number of times.

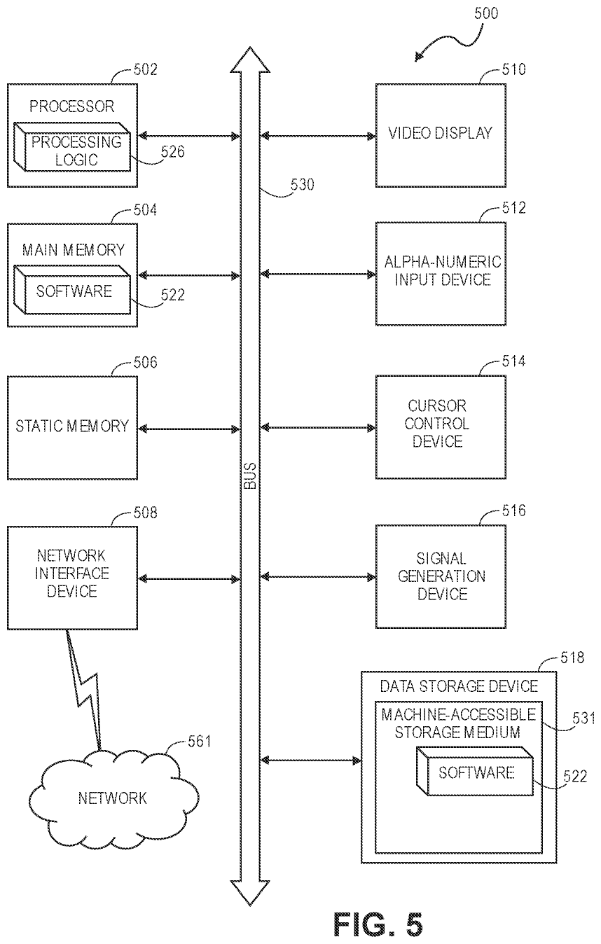

FIG. 5 illustrates a diagrammatic representation of a machine in the exemplary form of a computer system 500 within which a set of instructions, for causing the machine to perform any one or more of the methodologies described herein, may be executed. In alternative embodiments, the machine may be connected (e.g., networked) to other machines in a Local Area Network (LAN), an intranet, an extranet, or the Internet. The machine may operate in the capacity of a server or a client machine in a client-server network environment, or as a peer machine in a peer-to-peer (or distributed) network environment. The machine may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated, the term “machine” shall also be taken to include any collection of machines (e.g., computers) that individually or jointly execute a set (or multiple sets) of instructions to perform any one or more of the methodologies described herein.

The exemplary computer system 500 includes a processor 502, a main memory 504 (e.g., read-only memory (ROM), flash memory, dynamic random access memory (DRAM) such as synchronous DRAM (SDRAM) or Rambus DRAM (RDRAM), etc.), a static memory 506 (e.g., flash memory, static random access memory (SRAM), MRAM, etc.), and a secondary memory 518 (e.g., a data storage device), which communicate with each other via a bus 530.

Processor 502 represents one or more general-purpose processing devices such as a microprocessor, central processing unit, or the like. More particularly, the processor 502 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processor 502 may also be one or more special-purpose processing devices such as an application specific integrated circuit (ASIC), a field programmable gate array (FPGA), a digital signal processor (DSP), network processor, or the like. Processor 502 is configured to execute the processing logic 526 for performing the operations described herein.

The computer system 500 may further include a network interface device 508. The computer system 500 also may include a video display unit 510 (e.g., a liquid crystal display (LCD), a light emitting diode display (LED), or a cathode ray tube (CRT)), an alphanumeric input device 512 (e.g., a keyboard), a cursor control device 514 (e.g., a mouse), and a signal generation device 516 (e.g., a speaker).

The secondary memory 518 may include a machine-accessible storage medium (or more specifically a computer-readable storage medium) 532 on which is stored one or more sets of instructions (e.g., software 522) embodying any one or more of the methodologies or functions described herein. The software 522 may also reside, completely or at least partially, within the main memory 504 and/or within the processor 502 during execution thereof by the computer system 500, the main memory 504 and the processor 502 also constituting machine-readable storage media. The software 522 may further be transmitted or received over a network 520 via the network interface device 508.

While the machine-accessible storage medium 532 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, and optical and magnetic media.

In accordance with an embodiment of the present disclosure, a machine-accessible storage medium has instructions stored thereon which cause a data processing system to perform a method of measuring one or more properties of a photoresist layer. For example, the photoresist layer may be deposited to a first thickness. Then a first EM radiation source is used to measure the one or more properties of the photoresist layer without changing (chemically or morphologically) the photoresist layer. Thereafter, deposition of the photoresist layer may continue until a second thickness is reached. At the second thickness, the first EM radiation source is used to measure the one or more properties of the photoresist layer a second time.

Thus, methods for depositing a photoresist layer and measuring one or more properties of the photoresist layer is disclosed.

What is claimed is:

1. A method of monitoring a photoresist deposition process, comprising:
depositing a photoresist layer to a first thickness over a substrate;
measuring a property of the photoresist layer with a first electromagnetic (EM) radiation source;
depositing the photoresist layer to a second thickness over the substrate; and
measuring the property of the photoresist layer with the first EM radiation source.

2. The method of claim 1, wherein measuring the property of the photoresist layer with the first EM radiation source includes a short burst of EM radiation.

3. The method of claim 2, wherein the short burst is approximately two microseconds or less.

4. The method of claim 2, wherein the EM radiation has a wavelength between approximately 200 nm and approximately 800 nm.

5. The method of claim 4, wherein the EM radiation has a wavelength of approximately 400 nm or less.

6. The method of claim 1, wherein the property comprises one or more of thickness, surface roughness, chemical composition, complex dielectric constant, and complex refractive index.

7. The method of claim 1, wherein the EM radiation source is configured to provide ellipsometry, reflectometry, or fluorescence of photoelectron emittance.

8. The method of claim 1, wherein the property is used as part of a feedback loop in order to modify the photoresist deposition process.

9. The method of claim 8, wherein the feedback loop is used to modify a flow rate of one or more source gasses into a chamber where the photoresist layer is deposited.

10. The method of claim 1, wherein depositing the photoresist layer comprises a dry deposition process.

11. The method of claim 1, wherein the photoresist layer comprises a metal oxo material.

12. The method of claim 1, wherein the first EM radiation source emits radiation onto the photoresist layer that has a duration and power suitable for measuring the property without initiating a chemical reaction in the photoresist layer.

13. The method of claim 1, further comprising:
repeating the process any number of times in order to fully characterize the photoresist layer.

14. A semiconductor processing tool, comprising:
a chamber;
a susceptor configured to support a substrate;
a gas inlet for flowing one or more processing gasses into the chamber;
a window; and
an optical inspection tool for measuring one or more film properties of a photoresist layer on the substrate through the window, wherein the optical inspection tool is configured to provide a short burst of electromagnetic (EM) radiation that allows for measuring the one or more film properties of the photoresist layer without inducing a chemical change in the photoresist layer.

15. The semiconductor processing tool of claim 14, wherein the optical inspection tool uses inspection techniques including one or more of ellipsometry, reflectometry, and fluorescence of photoelectron emittance.

16. The semiconductor processing tool of claim 14, wherein the short burst has a duration of approximately 100 milliseconds or less.

17. The semiconductor processing tool of claim 14, wherein the EM radiation has a wavelength of approximately 400 nm or less.

18. The semiconductor processing tool of claim 14, further comprising a controller, wherein the optical inspection tool provides feedback to the controller in order to change a flow rate of one or more processing gasses through the gas inlet.

19. A semiconductor processing tool, comprising:
a chamber;
a susceptor for supporting a substrate in the chamber;
a window along a wall of the chamber, wherein the window allows for electromagnetic (EM) radiation to pass through the chamber; and
an inspection tool for measuring one or more film properties of a photoresist layer on the substrate through the window, wherein the inspection tool is configured to provide a short burst of EM radiation that allows for measuring the one or more film properties of the photoresist layer without inducing a chemical change in the photoresist layer, wherein the short burst has a duration of approximately 100 milliseconds or less, and wherein a wavelength of the EM radiation is approximately 400 nm or less.

20. The semiconductor processing tool of claim 19, wherein the inspection tool uses one or more of ellipsometry, reflectometery, or fluorescence of photoelectron emittance.
